(19) United States
(12) Patent Application Publication
(10) Pub. No.: US 2024/0079345 A1
(43) Pub. Date: Mar. 7, 2024

(54) ELECTROCONDUCTIVE MEMBER, METHOD FOR MANUFACTURING ELECTRONIC DEVICE, CONNECTION STRUCTURE, AND ELECTRONIC DEVICE

(71) Applicant: SHOWA DENKO MATERIALS CO., LTD., Tokyo (JP)

(72) Inventors: Masashi OHKOSHI, Tokyo (JP); Nozomu TAKANO, Tokyo (JP); Daisuke FUJIMOTO, Tokyo (JP); Hiroyuki IZAWA, Tokyo (JP); Tomohiko KOTAKE, Tokyo (JP); Kunihiko AKAI, Tokyo (JP); Yuka ITOH, Tokyo (JP); Shunsuke TAKAGI, Tokyo (JP)

(21) Appl. No.: 18/261,713

(22) PCT Filed: Jan. 18, 2022
(86) PCT No.: PCT/JP2022/001615

§ 371 Date: Jul. 17, 2023

(30) Foreign Application Priority Data
Jan. 19, 2021 (JP) 2021-006399

(51) Int. Cl. H01L 23/552; H01L 21/48; H01L 21/56; H01L 23/31; H01L 23/538

(52) U.S. Cl. CPC H01L 23/552; H01L 21/4857; H01L 21/565; H01L 23/3121; H01L 23/5383; H01L 23/5386; H01L 23/5389

(57) ABSTRACT

A conductive member includes an adhesive layer and a metal foil layer. The adhesive layer consists of an adhesive composition containing conductive particles. The metal foil layer is disposed on the adhesive layer. The conductive member can be used to form, for example, a predetermined metal film.

### TECHNICAL FIELD

The present disclosure relates to a conductive member, a method for manufacturing an electronic component, a connection structure, and an electronic device.

### BACKGROUND ART

In an electronic device including electronic components such as a semiconductor chip, the electronic components or the electronic device is covered with a shield member in order to reduce electromagnetic interference (EMI) due to a noise. As the shield member, for example, as described in Non-Patent Literature 1, a sheet metal shield is used, or a film of a shield material formed on the electronic components by sputtering or the like is used.

### CITATION LIST

### Non Patent Literature

Non Patent Literature 1: Masaaki Ishida, Keiju Yamada, and Takashi Yamayaki, “Electromagnetic Shielding Technologies for Semiconductor Packages”, Toshiba review vol. 67 No. 2 (2012), 2012.

### SUMMARY OF INVENTION

### Technical Problem

As described in Non-Patent Literature 1, according to the method of forming a shield film on an electronic component, a reduction in size and height of an electronic device can be accomplished in comparison to a configuration using sheet metal shield. However, a film forming process using sputtering requires long time to laminate a metal film such as the shield film to a predetermined thickness. Therefore, a new method capable of shortening the metal film forming time is desired.

An object of an aspect of the present disclosure is to provide a conductive member, a method for manufacturing an electronic device, a connection structure and an electronic device, capable of forming a metal film by a simple process.

### Solution to Problem

An aspect of the present disclosure relates to a conductive member. The conductive member includes an adhesive layer consisting of an adhesive composition containing conductive particles, and a metal foil layer disposed on the adhesive layer.

The conductive member includes the adhesive layer containing the conductive particles and the metal foil layer, and the metal foil layer is configured to be used as a metal film (for example, an electromagnetic wave shield film). In this case, the conductive member in which the metal foil layer is formed in advance is pasted to a portion where the metal film is necessary through the adhesive layer, thereby forming the metal film in the electronic device. According to this, when using the conductive member, a metal film can be formed by a simple process. In addition, since the metal foil layer is formed in advance, a uniform metal film is formed, and it is possible to provide an electronic device in which performance (for example, shield performance) due to the metal film is stable. Note that, the conductive member can be appropriately employed to form an electronic device that requires a metal film other than the shield film.

In the conductive member, the thickness of the metal foil layer may be 1 μm to 200 μm. In this case, the conductive member can be allowed to sufficiently function as a metal film, and a reduction in size and height of an electronic device to be manufactured can be accomplished. In this configuration, the thickness of the metal foil layer may be 3 μm or more, and may be 100 μm or less, 25 μm or less, or 18 μm or less. When the thickness of the metal foil layer is 25 μm or less or 18 μm or less, an additional reduction in size and height of the electronic device and the like can be accomplished.

In the conductive member, surface roughness Rz of an outer surface of the metal foil layer which is opposite to the adhesive layer may be 0.5 μm to 17 μm. In this case, the outer surface of the metal foil layer functioning as the metal film becomes a shiny surface with reduced surface roughness, and a rust prevention property of a metal film of an electronic device to be manufactured can be improved.

The conductive member may further include a holding film disposed on a surface of the metal foil layer which is opposite to the adhesive layer. In this case, when forming a metal film by using the conductive member, forming work becomes easy. In addition, since the metal foil layer is protected by the holding film when forming the metal film, the metal foil layer functioning as the metal film is prevented from being damaged during the forming work, and an electronic device in which performance of the metal film is excellent can be provided. In addition, even when unevenness exists on a surface of a semi-finished product of the electronic device when forming the metal film, the holding film functions as a buffering material and the conductive member is caused to sufficiently follow the unevenness, and thus a metal film having stable performance can be formed. Furthermore, with regard to formation of the metal film on a surface of the semi-finished product to be described later, a method including a process of pressing the conductive member against the surface of the semi-finished product is disclosed as an example. However, at this time, even when a few unevenness exists on the surface of the semi-finished product, the hold film is caused to function as a buffering material, and when the surface of the semi-finished product and the adhesive layer come into close contact with each other, the metal foil layer is caused to follow the unevenness, and thus stable performance can be provided.

In addition, another effect of the above-described holding film is as follows. The adhesive composition in the adhesive layer spreads in the unevenness on the surface of the semi-finished product of the electronic device, and thus occurrence of a gap due to the unevenness is suppressed and reliability of the electronic device on which the metal film is formed can be improved. Furthermore, in a case where the holding film is provided, the adhesive composition sufficiently spreads to the unevenness when being pressed, and thus occurrence of unevenness of the metal foil layer due to the unevenness on the surface of the semi-finished product is suppressed and a metal film with stable performance can be formed. That is, even when a few unevenness exists on the surface of the semi-finished product of the electronic device, flatness of the metal foil layer is likely to be secured after pressing, and in a case of using the metal film, for example, as a shield film, an electronic device with stable shield performance can be provided. When the flatness of the metal film is high as described above, it is easy to design an additional process of forming an additional resin layer or disposing another electronic device on the surface of the metal film, and a stable electronic device can be provided. In addition, even when unevenness exists on the surface of the semi-finished product of the electronic device, the adhesive layer can sufficiently spread to the unevenness due to the holding film when pressing the conductive member. According to this, it is possible to suppress expansion or contraction of the metal foil layer, or a damage such as stripes and cracks. According to this, it is possible to suppress an extreme deformation of the metal foil layer due to the holding film. Note that, the conductive member may include another holding film on a surface of the adhesive layer which is opposite to the metal foil layer. According to this, the adhesive layer can be protected.

In the above-described conductive member, the adhesive layer and the metal foil layer may be separately provided, and the adhesive layer is capable of adhering to the metal foil layer in use. In this case, since the adhesive layer and the metal foil layer can be prepared separately (for example, as a set of the conductive member for electromagnetic wave shield), for example, it is possible to improve the degree of freedom of work when preparing an electromagnetic wave shield by using the conductive member such as selection of a conductive member having a more optimal material configuration.

In the above-described conductive member, an average particle size of the conductive particles may be larger than the thickness of the adhesive layer. In this case, when connecting the metal foil layer to a ground member by using the conductive particles, the conductive particles are likely to come into contact with the metal foil layer and the ground member, and thus it is possible to more reliably realize the above-described connection by appropriately crushing and the like the conductive particles. The average particle size stated here is an average value of particle sizes obtained by performing particle size measurement through observation for 300 (pcs) arbitrary particles employing a scanning electron microscope (SEM). Note that, in a case where a particle shape is not spherical such as a case where the particles have protrusions, a diameter of a circle circumscribing a particle in a SEM image is set as the particle size of the particles. The same applies hereafter.

In the above-described conductive member, the conductive particles may include first conductive particles having a first average particle size, and second conductive particles having a second average particle size larger than the first average particle size. In this case, even when flatness of a semi-finished product and the like on which the conductive member is provided is low, the metal foil layer can be connected to the ground member by any of the conductive particles, and can stably form, for example, a shield film. In addition, in order to satisfactorily perform connection through the conductive particles, the conductive member may further contain conductive particles having an average particle size different from the first average particle size and the second average particle size. According to this, contact between the conductive particles and contact between the conductive particles and the metal foil layer are likely to occur, and thus connection between the metal foil layer and the ground member can be performed in a further satisfactory manner.

Another aspect of the invention relates to a method for manufacturing an electronic device. The method for manufacturing an electronic device includes providing a semi-finished product in which at least one electronic component is mounted on a wiring board, forming at least one metal conductive portion on the semi-finished product, encapsulating the electronic component on the semi-finished product with a resin, and disposing the conductive member having any of the above-described aspects on the metal conductive portion and electrically connecting the metal conductive portion and the metal foil layer with the conductive particles.

In the method for manufacturing an electronic device, a metal film of the electronic device is formed by using the above-described conductive member. In this case, the metal foil layer is formed in advance, and the conductive member is pasted to a portion where the metal film is necessary, thereby forming the metal film. According to this, the metal film can be formed by a simple process. In addition, in a case of depositing the metal film by sputtering, a sputtering thickness may be smaller at corners or the like of the semi-finished product in comparison to other portions. However, according to the manufacturing method, since the metal foil layer prepared in advance is used, it is possible to form a more uniform metal film. According to this, it is possible to provide an electronic device with stable performance (for example, shield performance) due to the metal film. Note that, in a case of forming the metal film by sputtering, in order to secure a thickness for sufficiently exhibiting the performance of the metal film, sputtering time tends to be lengthened. In addition, when flatness of the surface of the semi-finished product of the electronic device is low, the thickness of a sputtered layer is not uniform, and thus the performance due to the metal film also tends to decrease. Accordingly, a method of lengthening the sputtering time or a method of performing a polishing process for improving the flatness of the surface of the semi-finished product is necessary in the related art, and thus the entirety of processes are lengthened. In contrast, according to the above-described manufacturing method employing the conductive member, since the metal foil layer prepared in advance is disposed and formed on the surface of the semi-finished product, it is possible to obtain the stable performance due to the metal film by a simple method.

In the above-described method for manufacturing an electronic device, the encapsulating may be performed after the forming of the metal conductive portion. In this case, since the encapsulating with the resin is performed after forming the metal conductive portion on a surface of a ground layer on the semi-finished product, connection between the ground layer (ground member) and the metal conductive portion is performed in a satisfactory manner, and thus the metal conductive portion with sufficient connection strength can be formed. As a specific method of forming the metal conductive portion, a method of forming the metal conductive portion with a metal wire by using a wire bonding device, a method of connecting a metal member such as a metal wire, metal foil, and a metal plate to the ground layer through a solder or a metal material paste, a method of forming a photo- or heat-curable resin on a surface of the ground layer, forming a groove at a predetermined position by laser processing, cutting, or drilling, filling the groove with a metal material paste or plating to form the metal conductive portion, and removing the curable resin, a method of forming a photoresist layer to cover the ground layer, forming a groove at a predetermined position through exposure and development, filling the groove with a metal material paste or plating to form the metal conductive portion, and removing the photoresist layer, and the like can be used. In addition, since encapsulating with the resin is performed after forming the metal conductive portion connected to the ground layer by the above-described method, the metal conductive portion can be formed at a desired position. Note that, since the resin used in the encapsulating has a function of protecting internal electronic components from humidity, dust, or a deformation due to impact or heat, and has high moisture resistance and low thermal expansion, in order to perform the above-described groove processing after encapsulating, it is necessary to use a high-energy laser, a high-strength drill, and the like, but these are not necessary when employing the above-described method. In addition, in a case of forming the groove by the above-described method, it is necessary to perform processing without damaging the ground layer, and when a residue remains on the ground layer, there is a possibility that a problem may occur in the connection with the metal conductive portion. However, when employing the above-described method, the problem does not likely to occur.

In addition, the above-described method for manufacturing an electronic device may further include polishing a surface of the encapsulating resin so that a tip end of the metal conductive portion encapsulated with the resin is exposed in a case where the encapsulating is performed after the forming of the metal conductive portion. The polishing may be performed by using CMP slurry or a polishing pad. In addition, in the manufacturing method, the electrically connecting may be performed when performing the encapsulating. In this case, the forming of the metal film in the electronic device can be further shortened. For example, in the encapsulating, it is possible to use a method in which when forming a resin on a semi-finished product with a compression mold, the above-described conductive member is disposed on a mold side in advance, and the semi-finished product is covered with the mold and is molded with the resin.

In the above-described method for manufacturing an electronic device, the forming of the metal conductive portion may be performed after the encapsulating. In this case, for example, it is possible to use a method in which groove processing is performed on a resin after the encapsulating and the groove is filled with a metal. As a groove processing method, for example, a method of laser processing, cutting, drilling, or etching can be used. As a method of filling the groove with a metal, metal material pasting, plating, soldering, and the like can be used.

In the above-described method of manufacturing an electronic device, in the electrically connecting, at least one of heating and pressing may be performed with respect to the conductive member so that the conductive particles come into contact with the metal foil layer and the metal conductive portion of the semi-finished product, or the conductive particles are crushed by the metal foil layer and the metal conductive portion of the semi-finished product in order for the metal conductive portion and the metal foil layer to be electrically connected by the contact or crushed conductive particles. In this case, the metal foil layer that becomes the metal film and the conductive member connected to a ground wiring can be electrically connected in a more satisfactory manner. Even when metal conductive portions have a plurality of independent shapes, in the conductive member, since the conductive particles disposed in the adhesive layer come into contact with any metal conductive portion above described, and are connected to the metal foil layer, stable performance can be exhibited. In addition, in the above-described method for manufacturing an electronic component, a protective film may be provided on a surface of the metal foil layer which is opposite to the adhesive layer, and pressing may be performed with respect to the conductive member through the protective film.

In the above-described method of manufacturing an electronic device, the at least one metal conductive portion may include a plurality of metal conductive portions, and in the forming of the metal conductive portion, the plurality of metal conductive portions may be formed to surround the electronic component in a planar direction. In this case, it is possible to shield intruding substance (for example, electromagnetic waves) from a side portion of the electronic device by the plurality of metal conductive portions, and it is possible to manufacture an electronic device in which the intruding substance from the side portion is further suppressed. Note that, in the above-described manufacturing method, the plurality of metal conductive portions may be formed so that adjacent metal conductive portions are in contact with each other or adjacent metal conductive portions are separated from each other.

A still another aspect of the invention relates to a connection structure. The connection structure includes a conductive member having any one of the aspects, and a metal conductive portion that is provided on a semi-finished product and extends toward the conductive member. In the connection structure, the metal conductive portion and the metal foil layer are electrically connected through the conductive particles. In this case, the metal film can be formed by a simple process as described above. In addition, an electronic device with stable performance due to the metal film can be provided.

A further still another aspect of the present invention relates to an electronic device. The electronic device includes a semi-finished product in which at least one electronic component is mounted on a wiring board, and the connection structure. In this case, the metal film can be formed by a simple process as described above. In addition, an electronic device with stable performance due to the metal film can be provided.

### Advantageous Effects of Invention

According to the invention, as an aspect, a metal film can be formed by a simple process.

### BRIEF DESCRIPTION OF DRAWINGS

FIG. 1 is a cross-sectional view illustrating a conductive member according to an embodiment of the invention.

FIGS. 2A to 2C are views sequentially describing a first method for manufacturing an electronic device by using the conductive member illustrated in FIG. 1.

FIGS. 3A and 3B are views sequentially describing the first method for manufacturing an electronic device by using the conductive member illustrated in FIG. 1, and are views describing processes subsequent to FIG. 2C.

FIG. 4 is a view describing the first method for manufacturing an electronic device by using the conductive member illustrated in FIG. 1, and is a schematic plan view when viewing the process illustrated in FIG. 2A from an upper side.

FIGS. 5A and 5B are schematic cross-sectional views illustrating a process of connecting a metal foil layer to metal posts by conductive particles in an enlarged manner in the method for manufacturing an electronic device as illustrated in FIGS. 2A to 2C to FIG. 4, FIG. 5A is a view illustrating a state in which the conductive member is disposed, and FIG. 5B is a view illustrating a state in which connection by the conductive particles has been performed.

FIGS. 6A to 6C are views sequentially describing a second method for manufacturing an electronic device by using the conductive member illustrated in FIG. 1.

FIGS. 7A to 7C are views sequentially describing a third method for manufacturing an electronic device by using the conductive member illustrated in FIG. 1.

FIGS. 8A to 8E are cross-sectional views sequentially describing a method of forming a metal layer by sputtering.

FIGS. 9A and 9B is cross-sectional views illustrating modification examples of the conductive member illustrated in FIG. 1.

### DESCRIPTION OF EMBODIMENTS

Hereinafter, a conductive member according to an embodiment of the invention, and a method for manufacturing an electronic device by using the conductive member will be described with reference to the accompanying drawings. In the following description, the same reference numeral will be given to the same or equivalent portions, and redundant description will be omitted. In addition, positional relationships such as up, down, right, and left are based on positional relationships shown in the drawings unless otherwise stated. Dimensional ratios in the drawings are not limited to illustrated ratios.

In this specification, a numerical value range expressed by “to” includes numerical values described before and after “to” as a minimum value and a maximum value. In a numerical range described stepwise in this specification, an upper limit value or a lower limit value described in one numerical value range may be replaced with an upper limit value or a lower limit value of a numerical value range of another stage. In addition, in the numerical value range described in this specification, an upper limit value or a lower limit value of the numerical value range may be replaced with a value described in examples.

A conductive member according to an embodiment of the invention includes an adhesive layer consisting of an adhesive composition containing conductive particles, and a metal foil layer disposed on the adhesive layer. The thickness of the metal foil layer may be 1 μm to 200 μm, or 25 μm or less. The conductive member may be used to form, for example, an electromagnetic wave shield. The conductive member may further include a holding film disposed on at least one of a surface of the metal foil layer which is opposite to the adhesive layer and a surface of the adhesive layer which is opposite to the metal foil layer. In addition, in the conductive member, the adhesive layer and the metal foil layer may be separately provided, and the adhesive layer may adhere to the metal foil layer in use. An average particle size of the conductive particles may be larger than the thickness of the adhesive layer. The conductive particles may include first conductive particles having a first average particle size, and second conductive particles having a second average particle size larger than the first average particle size.

A method for manufacturing an electronic device according to an embodiment of the invention includes providing a semi-finished product in which at least one electronic component is mounted on a wiring board, forming at least one metal conductive portion on the semi-finished product, encapsulating the electronic component on the semi-finished product with a resin, and disposing the conductive member having any one of the above-described aspects on the metal conductive portion, and electrically connecting the metal conductive portion and the metal foil layer with the conductive particles. In the manufacturing method, the encapsulating may be performed after the forming of the metal conductive portion. In this case, the manufacturing method may further include polishing a surface of the encapsulating resin so that a tip end of the metal conductive portion encapsulated with the resin is exposed, and the polishing may be performed by using CMP slurry or a polishing pad. In addition, the electrically connecting may be performed when performing the encapsulating. In addition, in the manufacturing method, the forming of the metal conductive portion may be performed after the encapsulating. Furthermore, in the manufacturing method, in the electrically connecting, at least one of heating and pressing may be performed with respect to the conductive member so that the metal conductive portion and the metal foil layer are electrically connected through the conductive particles. In the manufacturing method, a protective film may be provided on a surface of the metal foil layer which is opposite to the adhesive layer, and pressing may be performed with respect to the conductive member through the protective film. The at least one metal conductive portion may include a plurality of metal conductive portions, and in the forming of the metal conductive portion, the plurality of metal conductive portions may be formed to surround the electronic component in a planar direction. In this case, the plurality of metal conductive portions may be formed so that adjacent metal conductive portions are in contact with each other or adjacent metal conductive portions are separated from each other.

A connection structure according to an embodiment of the invention includes the conductive member having any one of the above-described aspects, and a metal conductive portion that is provided on a semi-finished product and extends toward the conductive member. In the connection structure, the metal conductive portion and the metal foil layer are electrically connected through the conductive particles. An electronic device according to an embodiment of the invention includes a semi-finished product in which at least one electronic component is mounted on a wiring board, and the connection structure.

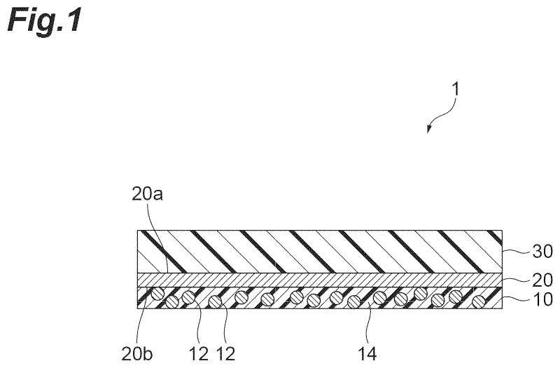

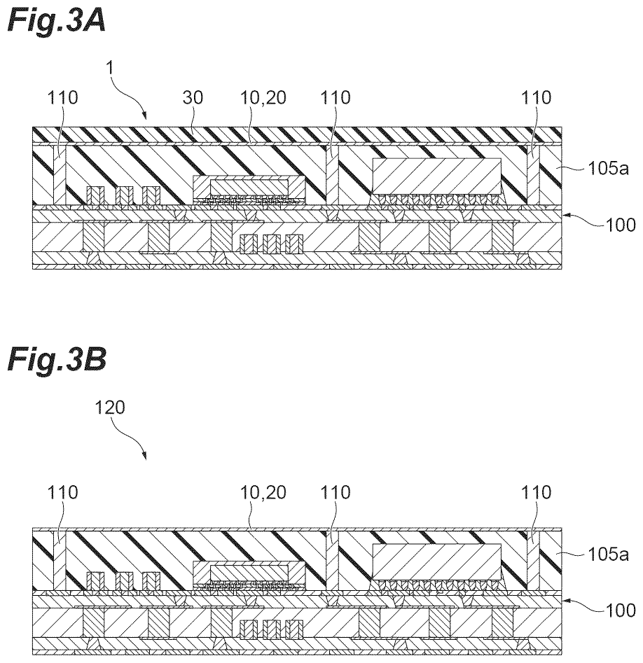

FIG. 1 is a cross-sectional view illustrating a conductive member according to an embodiment of the invention. As illustrated in FIG. 1, a conductive member 1 includes an adhesive layer 10, a metal foil layer 20, and a holding film 30. The conductive member 1 may be used as a member for forming a shield film of an electronic device 120 (refer to FIG. 3B). Details of a method for manufacturing an electronic device by using the conductive member 1 will be described later.

The adhesive layer 10 consists of an adhesive composition 14 containing conductive particles 12. For example, the adhesive layer 10 has a thickness of 1 μm to 100 μm. The adhesive composition 14 of the adhesive layer 10 is defined as a solid content other than the conductive particles 12. The adhesive composition 14 may be in a B-stage state in which a surface is dried, that is, a semi-cured state before manufacturing an electronic device by using the conductive member 1. The thickness of the adhesive layer can be measured by the following method. First, the conductive member 1 is sandwiched between two sheets of glass (thickness: approximately 1 mm) Next, the resultant laminate is cast by a resin composition consisting of 100 g of bisphenol A type epoxy resin (trade name: JER811, manufactured by Mitsubishi Chemical Corporation), and 10 g of curing agent (trade name: Epomount curing agent, manufactured by Refine Tec Ltd.). Then, cross-sectional polishing is performed by using a polishing machine, and the thickness of the adhesive layer is measured by using a scanning electron microscope (SEM) (trade name: SE-8020, manufactured by Hitachi High-Tech Science Corporation). In addition, the thickness of a metal foil layer to be described later is measured by the same method.

[Configuration of Conductive Particles]

The conductive particles 12 are approximately spherical conductive particles, and consist of metal particles consisting of a metal such as Au, Ag, Ni, Cu, Fe, Co, Mo, Zn, and solder, conductive carbon particles consisting of conductive carbon, or the like. The conductive particles 12 may be coated conductive particles including a core containing non-conductive glass, ceramic, plastic (polystyrene), or the like, and a coating layer that contains the metal or conductive carbon and coats the core. Among these, the conductive particles 12 may be coated conductive particles including a core that contains metal particles formed from a heat-fusible metal or plastic, and a coating layer that contains a metal or conductive carbon and coats the core.

In an embodiment, the conductive particles 12 include a core consisting of polymer particles (plastic particles) such as polystyrene, and a metal layer that coats the core. It is preferable that substantially the entirety of a surface of each of the polymer particles is covered with the metal layer, but a part of the surface of the polymer particle may not be covered with the metal layer and may be exposed within a range capable of maintaining a function as a connection material. For example, the polymer particles may be particles containing copolymers including at least one kind of monomer selected from styrene and divinyl benzene in a monomer unit.

The metal layer may be formed from various kinds of metals such as Ni, Ni/Au, Ni/Pd, Cu, NiB, Pd, Ag, Au, and Ru. The metal layer may be an alloy layer consisting of an alloy of Ni and Au, an alloy of Ni and Pd, or the like. The metal layer may have a multilayer structure including a plurality of metal layers. For example, the metal layer may include an Ni layer and an Au layer. The metal layer may be prepared by plating, deposition, sputtering, soldering, or the like. The metal layer may be a thin film (for example, a thin film formed by plating, deposition, sputtering, or the like). In a case where solder is used as the conductive particles 12, or in a case where solder is used in an outermost layer of the multilayer structure, the conductive member 1 is melt-bonded to the metal foil layer 20 and/or a ground member to obtain stable connection due to alloying. As the solder, solder containing tin or a tin alloy can be used. As the tin alloy, for example, an In—Sn alloy, an In—Sn—Ag alloy, an Sn—Au alloy, an Sn—Bi alloy, an Sn—Bi—Ag alloy, an Sn—Ag—Cu alloy, an Sn—Cu alloy, or the like can be used.

From the viewpoint of improving an insulating property, the conductive particles 12 may include an insulating layer. Specifically, for example, in conductive particles including a core (for example, polymer particles) and a coating layer such as a metal layer that coats the core, an insulating layer that further covers the coating layer may be provided on an outer side of the coating layer. The insulating layer may be an outermost layer located on an outermost surface of the conductive particles. The insulating layer may be a layer formed from an insulating material such as silica and an acrylic resin. Note that, the conductive particles 12 may have a configuration in which the insulating layer is not provided.

From the viewpoint of excellent dispersibility and conductivity, an average particle size Dp of the conductive particles 12 may be 1 μm or more, 2 μm or more, or 5 μm or more. From the viewpoint of excellent dispersibility and conductivity, the average particle size Dp of the conductive particles may be 100 μm or less, 50 μm or less, 30 μm or less, or 20 μm or less. From the above-described viewpoint, the average particle size Dp of the conductive particles may be 1 μm to 100 μm, 5 μm to 50 μm, 5 μm to 30 μm, or 5 μm to 20 μm.

From the viewpoint of excellent dispersibility and conductivity, a maximum particle size of the conductive particles 12 may be 1 μm or more, 2 μm or more, or 5 μm or more. From the viewpoint of excellent dispersibility and conductivity, the maximum particle size of the conductive particles 12 may be 100 μm or less, 50 μm or less, 30 μm or less, or 20 μm or less. From the viewpoint, the maximum particle size of the conductive particles may be 1 μm to 50 μm, 2 μm to 30 μm, or 5 μm to 20 μm.

The average particle size Dp of the conductive particles 12 may be larger than the thickness of the adhesive layer 10. In this case, a part of the conductive particles 12 is exposed from a surface of the adhesive layer 10 which is located on a side opposite to the metal foil layer 20, or the surface of the adhesive layer 10 which is located on a side opposite to the metal foil layer 20 follows the shape of the conductive particles 12 only in a portion where the conductive particles 12 exist and has a protruding shape. According to this configuration, in formation of a metal film to be described later, when connecting the metal foil layer 20 to a ground member (metal post 110) by using the conductive particles 12, the conductive particles 12 are appropriately crushed or the like, and thus the connection can be realized in a more satisfactory manner. In addition, the conductive particles 12 may be configured to include first conductive particles having a first average particle size and second conductive particles having a second average particle size larger than the first average particle size. That is, conductive particles 12 different in a particle size may be contained in the adhesive composition 14. Different particle sizes may be two or more kinds, for example, three kinds, four kinds, or the like. In this case, when manufacturing an electronic device 120, even when flatness of a portion where the conductive member 1 is provided is low, the metal foil layer 20 can be connected to the ground member (metal post 110) by any of the conductive particles, and the metal film can be stably formed.

In this specification, particle size measurement is performed through observation using a scanning electron microscope (SEM) with respect to arbitrarily 300 pcs of particles, an average value of obtained particle sizes is set as the average particle size Dp, and the largest value obtained is set as the maximum particle size of particles. Note that, in a case where the shape of the particles is not a spherical shape such as a case where the particles have a protrusion, a diameter of a circle circumscribing a particle in a SEM image is set as the particle size of the particles.

The content of the conductive particles 12 can be determined in correspondence with fineness of an electrode to be connected. For example, although not particularly limited, a blending amount of the conductive particles 12 is preferably 0.1% by volume or more, and more preferably 0.2% by volume or more on the basis of the total volume of the adhesive layer excluding the conductive particles. When the blending amount is 0.1% by volume or more, lowering of conductivity tends to be suppressed. The blending amount of the conductive particles 12 may be 80% by volume or less, 60% by volume or less, 30% by volume or less, or 10% by volume or less on the basis of the total volume of the adhesive layer excluding the conductive particles. Note that, “% by volume” is determined on the basis of a volume of each component before being cured at 23° C., but the volume of the component can be converted from the weight to the volume by using specific gravity. In addition, a suitable solvent (water, alcohol, or the like) that wets a component well without dissolving or swelling the component is put into a measuring cylinder or the like, and the “% by volume” can also be obtained as a volume increased when putting the component.

[Configuration of Adhesive Layer/Adhesive Composition]

The adhesive composition 14 constituting the adhesive layer 10 contains a curing agent, a monomer, and a film forming material. In a case of using an epoxy resin monomer, as the curing agent, an imidazole-based monomer, a hydrazide-based monomer, a boron trifluoride-amine complex, a sulfonium salt, amine imide, a polyamine salt, dicyandiamide, or the like can be used. It is preferable to coat the curing agent with a polyurethane-based or polyester-based polymeric substance, or the like to micro-capsulate the curing agent, or to mask the curing agent with isocyanate because a pot life is extended. On the other hand, in a case of using an acrylic monomer, as the curing agent, a curing agent such as a peroxide compound and an azo-based compound which are decomposed by heating and generate a free radical can be used.

The curing agent in a case of using an epoxy monomer is appropriately selected in accordance with desired connection temperature, connection time, storage stability, and the like. With regard to the curing agent, gelling time with an epoxy resin composition is preferably 10 seconds or shorter at a predetermined temperature from the viewpoint of high reactivity, and it is preferable that the gelling time with the epoxy resin composition does not vary after being stored in a thermostatic bath at 40° C. for 10 days from the viewpoint of storage stability. From the viewpoints, it is preferable that the curing agent is a sulfonium salt-based curing agent, a micro-capsulated imidazole-based curing agent, or an isocyanate-masked imidazole-based curing agent.

A curing agent in a case of using an acrylic monomer is appropriately selected in accordance with a desired connection temperature, connection time, storage stability, and the like. From the viewpoints of high reactivity and stage stability, organic peroxide or an azo-based compound in which a temperature of half-life of 10 hours is 40° C. or higher and a temperature of half-life of one minute is 180° C. or lower is preferable, and organic peroxide or an azo-based compound in which a temperature of half-life of 10 hours is 60° C. or higher and a temperature of half-life of one minute is 170° C. or lower is more preferable. The curing agents can be used alone or in combination, and may be used in combination with a decomposition accelerator, an inhibitor, or the like.

Even in a case of using any of the epoxy monomer and the acrylic monomer, when the connection time is set to 10 seconds or shorter, a blending amount of the curing agent is set to preferably 0.1 parts by mass to 40 parts by mass with respect to total 100 parts by mass of a monomer to be described later and a film forming material to be described later in order to obtain a sufficient reaction rate, and more preferably 1 part by mass to 35 parts by mass. When the blending amount of the curing agent is less than 0.1 parts by mass, there is a tendency that the sufficient reaction rate is not obtained, satisfactory adhesive strength and small connection resistance are less likely to be obtained. On the other hand, when the blending amount of the curing agent is more than 40 parts by mass, there is a tendency that fluidity of an adhesive decreases, connection resistance rises, or storage stability of the adhesive deteriorates.

In addition, in a case of using the epoxy resin monomer as the monomer, a bisphenol-type epoxy resin derived from epichlorohydrin and bisphenol A, bisphenol F, bisphenol AD, or the like, an epoxy novolac resin derived from epichlorohydrin and phenolic novolac or cresol novolac, various kinds of epoxy compounds having two or more glycidyl groups in one molecule such as glycidyl amine, glycidyl ether, biphenyl, and alicyclic, or the like can be used.

In a case of using the acrylic monomer, a radical polymerizable compound is preferably a substance having a functional group that is polymerized by radicals. Examples of the related radical polymerizable compound include (meth)acrylate, a maleimide compound, a styrene derivative, and the like. In addition, the radical polymerizable compound can be used in any of a monomer state and an oligomer state, and the monomer and the oligomer can be used in combination. With regard to the monomer, one kind may be used alone, or two or more kinds may be used in combination.

The film forming material is a polymer having an operation of making handling of a low-viscosity composition containing the curing agent and the monomer easy. When using the film forming material, the film is suppressed from being easily torn, cracked, or sticky, and the adhesive layer 10 of which handling is easy is obtained.

As the film forming material, a thermoplastic resin or a thermosetting resin is preferably used, and examples thereof include a phenoxy resin, a polyvinyl formal resin, a polyimide resin, a polystyrene resin, a polyvinyl butyral resin, a polyester resin, a polyamide resin, a xylene resin, a polyurethane resin, a polyacrylic resin, a polyester urethane resin, a polybismaleimide resin, and the like. Furthermore, siloxane bonds or a fluorine substituent may be contained in the polymers. The resins may be used alone or in combination of two or more kinds. Among the resins, it is preferable to use the phenoxy resin from the viewpoint of adhesive strength, compatibility, heat resistance, and mechanical strength. Particularly, in a case of using the epoxy monomer, when using the polybismaleimide material as the film forming material, a stronger cured product is obtained, and thus this is preferable from the viewpoint of the heat resistance or the mechanical strength.

As a molecular weight of the film forming material is larger, a film formability is more easily obtained, and a melt viscosity having an influence on fluidity of the film can be widely set. The molecular weight of the film forming material is preferably 5000 to 150000 in terms of a weight-average molecular weight, and more preferably 10000 to 80000. When the weight-average molecular weight is set to 5000 or more, satisfactory film formability is likely to be obtained, and when the weight-average molecular weight is set to 150000 or less, satisfactory compatibility with other components is likely to be obtained.

Note that, in this embodiment, the weight-average molecular weight represents a value measured by using a standard polystyrene calibration curve from a gel permeation chromatograph (GPC) under the following conditions.

(Measurement Conditions)
Device: GPC-8020 manufactured by Tosoh Corporation
Detector: RI-8020 manufactured by Tosoh Corporation
Column: Gelpack GLA160S+GLA150S manufactured by Showa Denko Materials Co., Ltd.
Sample concentration: 120 mg/3 mL
Solvent: Tetrahydrofuran
Injection amount: 60 μL
Pressure: 2.94×106 Pa(30 kgf/cm²)
Flow rate: 1.00 mL/min

In addition, the content of the film forming material is preferably 5% by weight to 80% by weight on the basis of the total amount of the curing agent, the monomer, and the film forming material, and more preferably 15% by weight to 70% by weight. When the content is set to 5% by weight or more, satisfactory film formability is likely to be obtained, and when the content is set to 80% by weight or less, a curable composition tends to exhibit satisfactory fluidity. In addition, the adhesive composition 14 that forms the adhesive layer 10 may further contain a filler, a softener, an accelerator, an anti-aging agent, a colorant, a flame retardant, a thixotropic agent, a coupling agent, a phenolic resin, a melamine resin, isocyanates, or the like.

In a case of containing the filler, an improvement of connection reliability can be further expected. A maximum diameter of the filler is preferably less than the particle size of the conductive particles 12, and the content of the filler is preferably 5 parts by volume to 60 parts by volume with respect to 100 parts by volume of the adhesive layer. When the content of the filler is 5 parts by volume to 50 parts by volume, satisfactory connection reliability tends to be obtained.

[Configuration of Metal Foil Layer]

The metal foil layer 20 is formed from, for example, copper foil, aluminum foil, nickel foil, stainless steel, titanium, platinum, or the like. For example, the metal foil layer 20 has a thickness of 1 μm to 200 μm, and may have a thickness of 10 μm to 20 μm. The thickness of the metal foil layer 20 may be 3 μm or more, 100 μm or less, 25 μm or less, or 18 μm or less. The thickness of the metal foil layer stated here is a thickness including surface roughness Rz. Since the metal foil layer 20 is formed in advance, the film thickness is uniform.

Surface roughness of a surface 20b opposite to one surface 20a of the metal foil layer 20 is not particularly limited. Surface roughness Rz of the surface 20b of the metal foil layer 20 on which the adhesive layer 10 is formed may be smaller than the average particle size of the conductive particles 12. According to this, connection through the conductive particles 12 can be more stable. Surface roughness Rz of the surface 20a and the surface roughness Rz of the surface 20b in the metal foil layer 20 may be equal to each other or different from each other. In this case, the surface 20a and the surface 20b of the metal foil layer 20 may be a shiny surface and a matte surface, respectively. The surface roughness Rz of the surface 20a that is a shiny surface is smaller than the surface roughness Rz of the surface 20b that is a matte surface. The metal foil layer 20 may be arranged so that the shiny surface becomes the holding film 30 side opposite to the adhesive layer 10. That is, the metal foil layer 20 may be arranged so that a smooth surface in the metal foil layer 20 becomes an outer surface in the electronic device 120. The surface roughness Rz of the shiny surface may be 0.01 μm or more, 0.5 μm or more, or 1.0 μm or more. The surface roughness Rz of the shiny surface may be 17 μm or less, 10 μm or less, 8.0 μm or less, 5.0 μm or less, or 3.0 μm or less. The surface roughness Rz of the shiny surface may be, for example, 0.01 μm to 17 μm, or 0.5 μm to 3.0 μm. The surface roughness Rz of the matte surface of the metal foil layer 20 may be, for example, 17 μm or more. The surface roughness Rz represents 10-point average roughness Rzjis measured on the basis of a method defined JIS standard (JIS B 0601-2001), and is a value measured by using a commercially available surface roughness shape measuring device. For example, the surface roughness Rz can be measured by using a nano search microscope (SFT-3500, manufactured by SHIMADZU CORPORATION).

[Holding Film]

The holding film 30 is a member configured to protect the adhesive layer 10 and the metal foil layer 20 and to make forming work easy when forming the metal film by using the conductive member 1. The holding film 30 is configured to be disposed on the metal foil layer 20, for example, by adhesion, and protects the metal foil layer 20. Another holding film may be disposed on a rear surface of the adhesive layer 10 to protect the adhesive layer 10. For example, the holding film 30 and the other holding film are constituted by a resin such as a fluororesin, polyethylene terephthalate, or polyimide, or paper. Note that, the conductive member 1 may be a configuration in which the holding film 30 is not provided, and in this case, the surface 20a of the metal foil layer 20 of the conductive member 1 enters an exposed state.

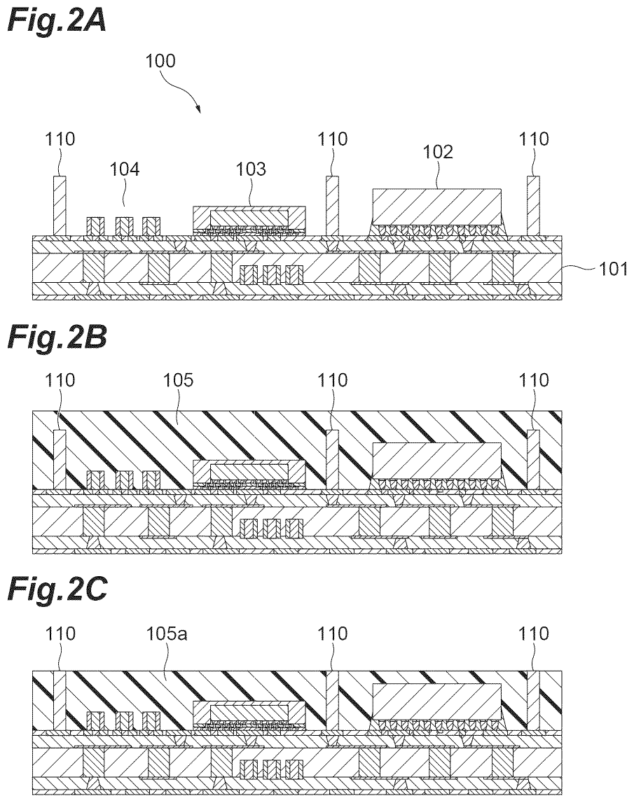

Next, a method of forming the metal film of the electronic device 120 by using the conductive member 1 will be described with reference to FIGS. 2A to 2C and FIGS. 3A and 3B. FIGS. 2A to 2C and FIGS. 3A and 3B are views sequentially illustrating a first manufacturing method of the electronic device 120 by using the conductive member 1. Note that, in the following description of the manufacturing method, respective processes may be performed separately, or another process may be performed in parallel while performing one process.

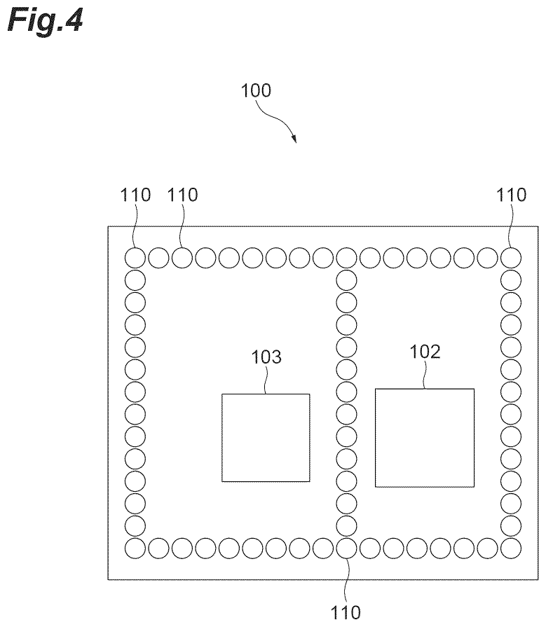

First, as illustrated in FIG. 2A, a semi-finished product 100 in which electronic components 102, 103, and 104 are mounted on a wiring board 101 is prepared. For example, the wiring board 101 is constituted by a multilayer board, a core board, a coreless multilayer plate, a flexible multilayer plate, a build-up multilayer plate, or a multilayer rewiring layer. For example, the electronic components 102 to 104 are semiconductor devices such as semiconductor chips, or small-sized electronic components such as a chip capacitor and a chip resistor. The electronic components 102 to 104 may be other electronic components. In addition, metal posts 110 (metal conductive portion) are formed on the wiring board 101 to surround the electronic component 102, and the electronic components 103 and 104 in a planar direction (refer to FIG. 4). For example, the metal post 110 has a cylindrical shape and is formed from copper or the like. For example, the metal post 110 can be formed by a method of filling a hole (via) formed by a photoresist through plating, a method of filling the via with metal paste, a method of randomly disposing a metal wire by a wire bonding device in a post shape, a circular arc shape, or a shape of a plurality of overlapping circular arcs, and the like. In an example illustrated in FIG. 4, the metal posts 110 are formed in contact with adjacent metal posts 110, but may be formed to be separated from each other. At least a part of a plurality of the metal posts 110 is connected to a ground wiring provided in the wiring board 101. In FIG. 4, the metal posts 110 have an independent shape in a plan view, but an interval of the metal posts may be appropriately adjusted in accordance with a required electromagnetic shield effect. When the metal posts 110 have shapes communicating with each other without a gap, a shielding property in a case of using the metal film, for example, as a shield film becomes reliable, and thus this configuration is preferable. On the other hand, when an interval exists between the metal posts 110, there is an advantage that the interval is filled with a mold resin, and strength in a lateral direction increases.

Next, as illustrated in FIG. 2B, the electronic components 102 to 104 on the semi-finished product 100 and the metal posts 110 are encapsulated with a resin to form a resin encapsulating layer 105. Examples of an encapsulating resin constituting the resin encapsulating layer 105 include an epoxy resin, and the like. The encapsulating resin may contain inorganic materials such as silica and aluminum oxide. Then, as illustrated in FIG. 2C, after the resin encapsulating layer 105 is formed, polishing is performed so that a tip end of each of the metal posts 110 is exposed from a surface of the resin encapsulating layer 105, thereby forming a resin encapsulating layer 105a. As a polishing agent that is used in the polishing, for example, CMP slurry or a polishing pad can be used. Due to the polishing, surfaces of the resin encapsulating layer 105a and the metal posts 110 are flushed with each other, and when disposing and pressing the conductive member 1, the metal posts 110 and the metal foil layer 20 can be stably connected through the conductive particles 12. In addition, since flatness is secured, flatness of the metal foil layer 20 is also secured. Accordingly, elongation or breakage is less likely to occur and stable performance can be secured. In addition, in a case of using a polishing material having a chemically reactive (etching) operation in the polishing, the metal posts 110 may be further recessed in comparison to the resin encapsulating layer 105a. Even in this case, the conductive member 1 connects the metal posts 110 (metal conductive portions) and the metal foil layer 20 by the conductive particles 12, and a resin in the adhesive layer 10 fills a step between the metal posts 110 and the resin encapsulating layer 105a. Accordingly, an extreme deformation or breakage of the metal foil layer 20 is prevented, and stable performance can be exhibited.

In addition, in formation of a metal layer using sputtering in the related art, it is necessary to secure flatness by polishing at a high level in order to obtain the thickness of the metal layer capable of obtaining sufficient performance (for example, a shielding property) in a short time. That is, in a case where a surface with unevenness exists, isotropic formation of the metal layer which is peculiar to the sputtering leads to a portion where the thickness of the metal layer is partially small, and thus polishing for securing high flatness is necessary. In contrast, in the method using the conductive member 1, even when the surface polishing after the encapsulating with the resin is roughly performed, a stable metal layer can be obtained. In other words, since the adhesive layer 10 of the conductive member 1 fills unevenness occurred due to the rough polishing, and the conductive particles 12 perform connection between the metal posts 110 (metal conductive portions) and the metal foil layer 20 in a satisfactory manner, it is possible to form the metal foil layer 20 with a thickness secured in advance (for example, with an electromagnetic shielding function), and stable performance can be obtained. Accordingly, when using the conductive member 1, simplification and time shortening in the polishing process can also be realized. Specifically, a number of times of multi-step precision polishing using the CMP slurry or the polishing pad is reduced to shorten time, or simplification and time shortening can be realized by using mechanical cutting or the like instead of the multi-step precision polishing.

Next, as illustrated in FIG. 3A, the conductive member 1 for forming a metal film is disposed on the metal posts 110 and the resin encapsulating layer 105a. At this time, the conductive member 1 is disposed so that the adhesive layer 10 faces the metal posts 110 and the resin encapsulating layer 105a. The conductive member 1 can be pasted to the metal posts 110 and the resin encapsulating layer 105a by the adhesive layer 10. Then, the conductive member 1 is heated and pressed to be laminated on the resin encapsulating layer 105a.

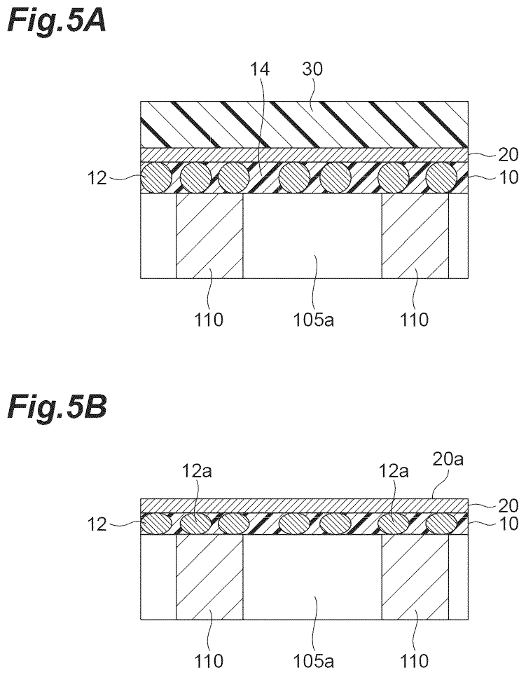

In the lamination, as illustrated in FIGS. 5A and 5B, due to pressing through the holding film 30, conductive particles located between the holding film 30 and the metal posts 110 among the conductive particles 12 of the conductive member 1 are crushed, and the metal posts 110 and the metal foil layer 20 are electrically connected by crushed conductive particles 12a. In addition, due to the heating and pressing in the lamination, the adhesive layer 10 of the conductive member 1 is cured and is fixed to the resin encapsulating layer 105a. As described above, in a connection structure illustrated in FIGS. 5A and 5B, the conductive member 1 and the metal posts 110 extending toward the conductive member 1 are provided, and the metal posts 110 and the metal foil layer 20 are electrically connected by the conductive particles 102a. Note that, at this time, the holding film 30 functions as a buffering material, and the conductive member 1 can be sufficiently caused to follow the surface unevenness of the semi-finished product.

Next, when the metal foil layer 20 is mechanically and electrically connected to the metal posts 110 by the conductive particles 12a (refer to FIG. 5B), as illustrated in FIG. 3B, the holding film 30 is peeled from the metal foil layer 20. As described above, the electronic device 120 including the metal foil layer 20 as a metal film is formed. In the electronic device 120, for example, intrusion of a noise from an upward side is suppressed by the metal foil layer 20, and intrusion of a noise from a side portion is suppressed by the metal posts 110.

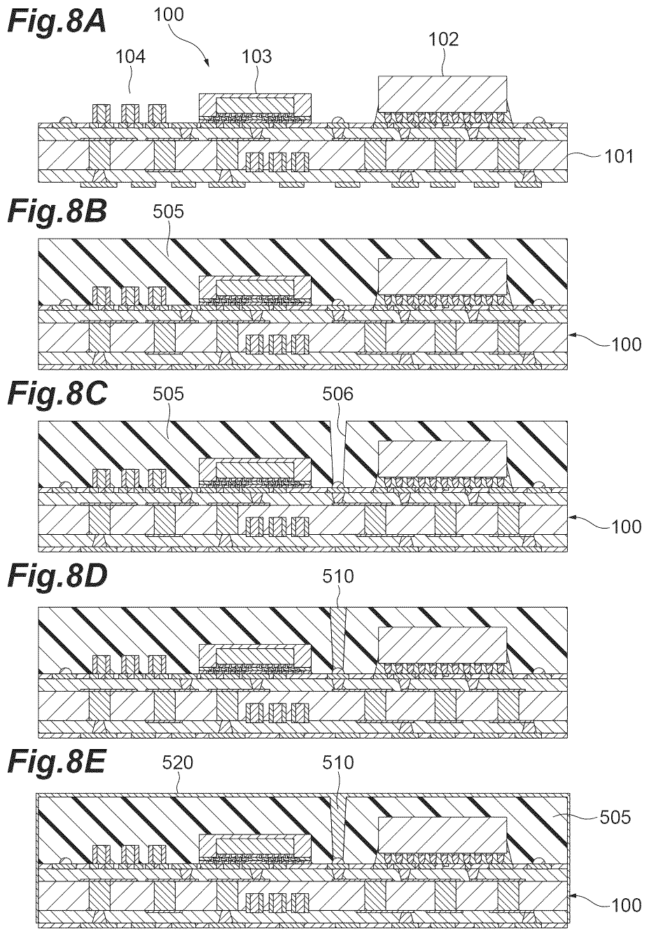

Here, description will be given of an advantageous effect of the above-described manufacturing method as being compared with a method of forming a metal film by sputtering. First, the method of forming the metal film by the sputtering will be described with reference to FIGS. 8A to 8E. FIGS. 8A to 8E are cross-sectional views sequentially illustrating the method of forming the metal film by the sputtering.

As illustrated in FIG. 8A, in the method of forming the metal film by the sputtering, first, the semi-finished product 100 in which the electronic components 102 to 104 are mounted on the wiring board 101 is prepared. Then, as illustrated in FIG. 8B, the electronic components 102 to 104 are encapsulated with a resin to form a resin encapsulating layer 505. Next, as illustrated in FIG. 8C, a hole 506 is formed in the resin encapsulating layer 505 with a laser. As illustrated in FIG. 8D, metal paste such as silver paste is injected into the hole 506 and is solidified therein to form a metal conductive portion 510. Then, as illustrated in FIG. 8E, a metal film 520 is formed to be electrically connected to the metal conductive portion 510 on the resin encapsulating layer 505. In the sputtering, for example, working time of approximately 60 minutes is required to form a metal film having a thickness of approximately 5 μm to 10 μm, and in a case of forming a plurality of different metal layers so as to improve adhesiveness between an encapsulating material and an organic material, working time of 60 minutes or longer is further required.

In contrast, in the manufacturing method according to the above-described embodiment, the metal film of the electronic device 120 is formed by using the conductive member 1. That is, in the manufacturing method, the conductive member 1 in which the metal foil layer 20 is formed in advance is pasted to a portion (on the resin encapsulating layer 105a and the metal posts 110) where the metal film is necessary to form the metal film. According to this, metal film forming time can be significantly shortened in comparison to the method using the sputtering. In addition, in a case of depositing the metal film by sputtering, a sputtering thickness may be smaller at corners or the like of the semi-finished product 100 in comparison to other portions. However, according to the manufacturing method according to this embodiment, since the metal foil layer 20 prepared in advance is used, it is possible to form a more uniform metal film. According to this, it is possible to provide the electronic device 120 with stable performance (for example, shield performance) due to the metal film.

In addition, in the method for manufacturing an electronic device according to this embodiment, the thickness of the metal foil layer 20 of the conductive member 1 that is used may be 1 μm to 200 μm. In this case, the conductive member 1 can be allowed to sufficiently function as a metal film, and a reduction in size and height of the electronic device 120 to be manufactured can be accomplished.

In addition, in the method for manufacturing an electronic device according to this embodiment, in the conductive member 1, surface roughness Rz of an outer surface of the metal foil layer 20 which is opposite to the adhesive layer 10 may be 0.5 μm to 17 μm. In this case, the outer surface of the metal foil layer 20 functioning as the metal film becomes a shiny surface with reduced surface roughness, and a rust prevention property of the metal film of the electronic device 120 to be manufactured can be improved.

In addition, in the method for manufacturing an electronic device according to this embodiment, the conductive member 1 that is used may further include the holding film 30 that adheres to a surface of the metal foil layer 20 which is opposite to the adhesive layer 10. In this case, when forming the metal film by using the conductive member 1, it is easy to perform formation work. In addition, since the metal foil layer 20 is protected by the holding film 30 when forming the metal film, the metal foil layer 20 functioning as the metal film is prevented from being damaged during the forming work, and the electronic device 120 in which performance of the metal film is excellent can be provided. The holding film also has an advantage of functioning as a buffer material at the time of pressing.

In addition, in the method for manufacturing an electronic device according to this embodiment, in the conductive member 1 that is used, the average particle size Dp of the conductive particles 12 may be larger than the thickness of the adhesive layer 10. In this case, when connecting the metal foil layer 20 to the metal posts 110 by using the conductive particles 12, the above-described connection can be realized in a more satisfactory manner by appropriately crushing the conductive particles 12, or the like.

In addition, in the method for manufacturing an electronic device according to this embodiment, in the conductive member 1 that is used, the conductive particles 12 may include first conductive particles having a first average particle size and second conductive particles having a second average particle size larger than the first average particle size. In this case, even when flatness of the resin encapsulating layer 105a or the like in the semi-finished product 100 on which the conductive member 1 is provided is low, the metal foil layer 20 can be connected to the metal posts 110 by any of the conductive particles 12, and the metal film can be stably formed, for example, as a shield film.

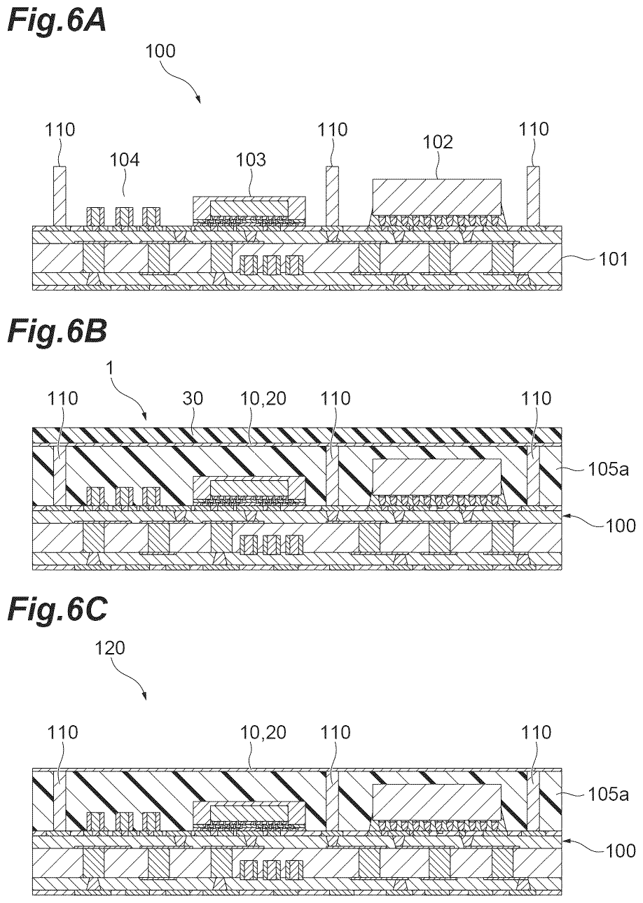

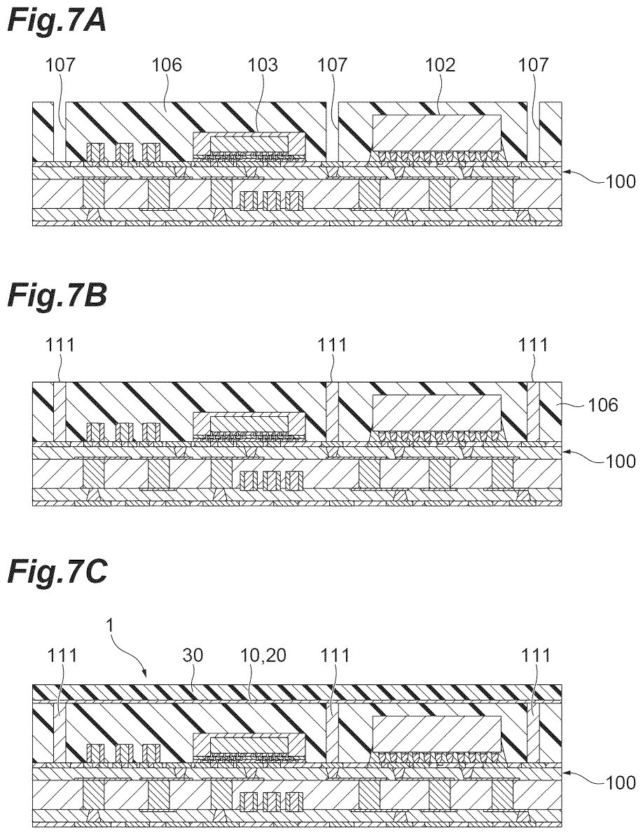

Hereinbefore, the embodiment of the invention has been described in detail, but the invention is not limited to the above-described embodiment and is applicable to various embodiments. For example, in the above-described embodiment, a method of forming the metal film on the electronic device 120 by using the conductive member 1, but there is no limitation thereto. For example, the metal film can be formed on the electronic device 120 by using a method illustrated in FIGS. 6A to 6C or FIGS. 7A to 7C. The metal film that is formed by the method is, for example, an electromagnetic wave shielding metal film. FIGS. 6A to 6C are views sequentially illustrating a second method for manufacturing the electronic device 120 by using the conductive member 1. FIGS. 7A to 7C are views sequentially illustrating a third method for manufacturing the electronic device 120 by using the conductive member 1.

As illustrated in FIG. 6A, in the second manufacturing method, as in the first manufacturing method, the semi-finished product 100 in which the electronic components 102 to 104 are mounted on the wiring board 101 is prepared, and the metal posts 110 are formed on the wiring board 101 (refer to FIG. 4). Then, when forming the resin encapsulating layer 105a, the conductive member 1 is provided in a mold (not illustrated) and compression molding is performed. At this time, connection between the metal foil layer 20 and the metal posts 110 by the conductive particles 12, and adhesion between the adhesive layer 10 and the resin encapsulating layer 105a are performed. In this manufacturing method, since compression molding is used, polishing of the resin encapsulating layer, and the like are not necessary. Then, as in the first manufacturing method, as illustrated in FIG. 6C, the holding film 30 is peeled from the metal foil layer 20 to form the electronic device 120. According to this manufacturing method, a similar operational effect as in the first manufacturing method can be obtained, and the metal film can be formed by a simpler process.

In addition, in a third manufacturing method, as in the first manufacturing method, the semi-finished product 100 in which the electronic components 102 to 104 are mounted on the wiring board 101 is prepared (refer to FIG. 2A). Then, as illustrated in FIG. 7A, the electronic components 102 to 104 on the wiring board 101 are encapsulated with a resin to form a resin encapsulating layer 106. The resin encapsulating layer 106 can be formed by using a similar resin as in the resin encapsulating layer 105 or 105a. Then, holes 107 are formed at positions corresponding to the metal posts 110 in the first manufacturing method by imprinting, laser processing, cutting, drilling, or etching. For example, the holes 107 are formed to surround the electronic component 102, and the electronic components 103 and 104 in a planar direction. Then, metal paste such as copper paste is injected into the hole 107 and is solidified therein to form metal conductive portions 111. The metal conductive portions 11 may be formed by using plating or soldering instead of the metal paste. At least a part of the metal conductive portions 111 is connected to a ground wiring provided in the wiring board 101.

Next, as illustrated in FIG. 7C, as in the first manufacturing method, the conductive member 1 is disposed on the metal conductive portions 111 and the resin encapsulating layer 106. At this time, the conductive member 1 is disposed so that the adhesive layer 10 faces the metal conductive portions 111 and the resin encapsulating layer 106. The conductive member 1 can be pasted to the metal conductive portions 111 and the resin encapsulating layer 106 by the adhesive layer 10. Then, the conductive member 1 is heated and pressed to be laminated on the resin encapsulating layer 106. At this time, due to pressing through the holding film 30, as illustrated in FIGS. 5A and 5B, conductive particles located between the holding film 30 and the metal conductive portions 111 among the conductive particles 12 of the conductive member 1 are crushed, and the metal conductive portions 111 and the metal foil layer 20 are electrically connected by crushed conductive particles 12a. In addition, due to the heating and pressing in the lamination, the adhesive layer 10 of the conductive member 1 is cured and is fixed to the resin encapsulating layer 106. Then, the holding film 30 is peeled from the metal foil layer 20. As described above, the electronic device 120 including the metal film can also be formed by the third manufacturing method by using the conductive member 1. According to the manufacturing method, a similar operational effect as in the first manufacturing method can be obtained, and the metal film can be formed by a simpler process.

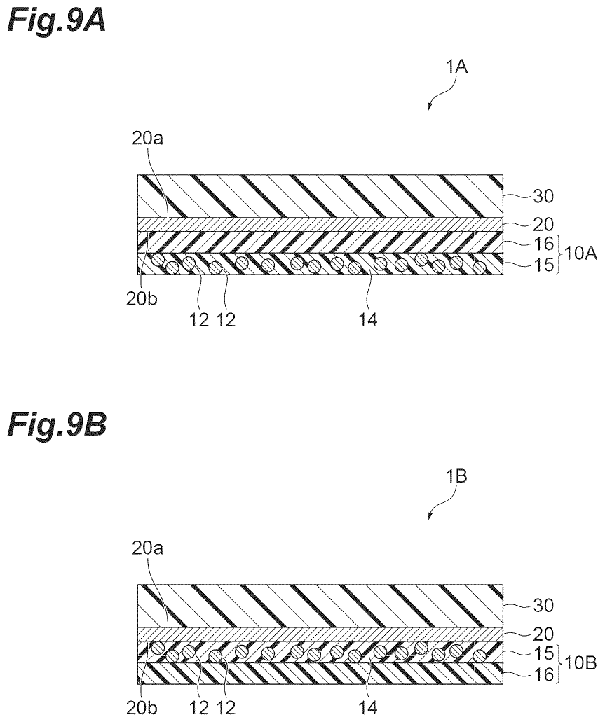

Note that, as illustrated in FIGS. 9A and 9B, the conductive member that is used in the above-described various manufacturing method may be a conductive member 1A or 1B including adhesive layers 10A and 10B including a first adhesive layer 15 consisting of the conductive particles 12 and an adhesive composition, and a second adhesive layer 16 consisting of an adhesive composition. In the conductive member 1A or 1B, the first adhesive layer 15 and the second adhesive layer 16 may consist of the above-described adhesive composition 14. The adhesive composition in the first adhesive layer 15 and the second adhesive layer 16 may be the same as each other, or may be different from each other. The conductive member 1A may have a configuration in which the metal foil layer 20, the second adhesive layer 16, and the first adhesive layer 15 are laminated in this order as illustrated in FIG. 9A, or a configuration in which the metal foil layer 20, the first adhesive layer 15, and the second adhesive layer 16 are laminated in this order as illustrated in FIG. 9B.

In addition, in the above-described embodiment, description has been given of a case where the conductive member 1 is a member in which the adhesive layer 10 and the metal foil layer 20 adhere to each other as an example, but in the conductive member 1 in this embodiment, the adhesive layer 10 and the metal foil layer 20 may be provided separately, and may constitute a set product in which the metal the adhesive layer 10 can adherer to the metal foil layer 20 in use. In this case, since the adhesive layer 10 and the metal foil layer 20 can be prepared separately (as a set of the conductive member for forming a metal film), it is possible to improve the degree of freedom of working when forming the metal film by using the conductive member such as selection of the conductive member having a more optimal material configuration.

### REFERENCE SIGNS LIST

1, 1A, 1B: conductive member, 10, 10A, 10B: adhesive layer, 12, 12a: conductive particle, 14: adhesive composition, 15: first adhesive layer, 16: second adhesive layer, 20: metal foil layer, 20a: surface, 20b: surface, 30: holding film, 100: semi-finished product, 101: wiring board, 102, 103, 104: electronic component, 105, 105a, 106: resin encapsulating layer, 107: hole, 110: metal post (metal conductive portion), 111: metal conductive portion, 120: electronic device.

1. A conductive member, comprising:
an adhesive layer consisting of an adhesive composition containing conductive particles; and
a metal foil layer disposed on the adhesive layer.

2. The conductive member according to claim 1,
wherein the conductive member is used to form an electromagnetic wave shield.

3. The conductive member according to claim 1,
wherein the thickness of the metal foil layer is 1 μm to 200 μm.

4. The conductive member according to claim 3,
wherein the thickness of the metal foil layer is 25 μm or less.

5. The conductive member according to 4 claim 1, further comprising:
a holding film disposed on at least one of a surface of the metal foil layer which is opposite to the adhesive layer and a surface of the adhesive layer which is opposite to the metal foil layer.

6. The conductive member according to claim 1,
wherein the adhesive layer and the metal foil layer are separately provided, and the adhesive layer is capable of adhering to the metal foil layer in use.

7. The conductive member claim 1,
wherein an average particle size of the conductive particles is larger than the thickness of the adhesive layer.

8. The conductive member claim 1,
wherein the conductive particles include first conductive particles having a first average particle size, and second conductive particles having a second average particle size larger than the first average particle size.

9. The conductive member according to claim 1,
wherein the adhesive layer includes a first adhesive layer consisting of the conductive particles and an adhesive composition, and a second adhesive layer consisting of an adhesive composition.

10. A method for manufacturing an electronic device, comprising:
providing a semi-finished product in which at least one electronic component is mounted on a wiring board;
forming at least one metal conductive portion on the semi-finished product;
encapsulating the electronic component on the semi-finished product with a resin; and
disposing the conductive member according to claim 1 on the metal conductive portion, and electrically connecting the metal conductive portion and the metal foil layer with the conductive particles.

11. The method for manufacturing an electronic device according to claim 10,
wherein the encapsulating is performed after the forming of the metal conductive portion.

12. The method for manufacturing an electronic device according to claim 11, further comprising:
polishing a surface of the encapsulated resin so that a tip end of the metal conductive portion encapsulated with the resin is exposed.

13. The method for manufacturing an electronic device according to claim 12,
wherein the grinding is performed by using CMP slurry or a polishing pad.

14. The method for manufacturing an electronic device according to claim 11,
wherein the electrically connecting is performed when the encapsulating is performed.

15. The method for manufacturing the electronic device according to claim 10,
the forming of the metal conductive portion is performed after the encapsulating.

16. The method for manufacturing an electronic device according to claim 1,
wherein in the electrically connecting, at least one of heating and pressing is performed with respect to the conductive member so that the metal conductive portion and the metal foil layer are electrically connected through the conductive particles.

17. The method for manufacturing an electronic device according to claim 1,
wherein a protective film is provided on a surface of the metal foil layer which is opposite to the adhesive layer, and pressing is performed with respect to the conductive member through the protective film.

18. The method for manufacturing an electronic device according to claim 1,
wherein the at least one metal conductive portion includes a plurality of metal conductive portions, and
in the forming of the metal conductive portion, the plurality of metal conductive portions are formed to surround the electronic component in a planar direction.

19. The method for manufacturing an electronic device according to claim 18,
wherein the plurality of metal conductive portions are formed so that adjacent metal conductive portions are in contact with each other or adjacent metal conductive portions are separated from each other.

20. A connection structure, comprising:
the conductive member according to claim 1; and
a metal conductive portion that is provided on a semi-finished product and extends toward the conductive member.
wherein the metal conductive portion and the metal foil layer are electrically connected through the conductive particles.

21. An electronic device, comprising:
a semi-finished product in which at least one electronic component is mounted on a wiring board; and
the connection structure according to claim 20.
